(19) United States
(12) Patent Application Publication
(10) Pub. No.: US 2026/0202738 A1
(43) Pub. Date: Jul. 16, 2026

(54) METHOD AND APPARATUS FOR PARTICLE BEAM-INDUCED ETCHING OF A DEFECT OF A MICROLITHOGRAPHIC PHOTOMASK

(71) Applicant: Carl Zeiss SMT GmbH, Oberkochen (DE)

(72) Inventors: Daniel Rhinow, Frankfurt (DE); Christian Preischl, Mainz (DE)

(21) Appl. No.: 19/179,460

(22) Filed: Apr. 15, 2025

(30) Foreign Application Priority Data
Apr. 17, 2024 (DE) 102024110764.2

(51) Int. Cl. G03F 1/74; G03F 1/80

(52) U.S. Cl. CPC G03F 1/74; G03F 1/80

(57) ABSTRACT

Method for particle beam-induced etching of a defect of a microlithographic photomask, including the steps of:
a) providing an activating particle beam and a first gaseous component, which is activatable by the particle beam, at a surface of the photomask in a region of the defect for the purpose of etching the defect, and subsequently
b) providing an oxygen-containing second gaseous component with a spontaneously oxidizing effect at the surface of the photomask in a passivation region that encompasses the region of the defect, for the purpose of passivating the surface.

### CROSS-REFERENCE TO RELATED APPLICATION

This application claims benefit under 35 U.S.C. § 119 to German Application No. 10 2024 110 764.2, filed on Apr. 17, 2024. The entire disclosure of this application is incorporated by reference.

### TECHNICAL FIELD

The present invention relates to a method and an apparatus for particle beam-induced etching of a defect of a microlithographic photomask.

### BACKGROUND

Microlithography is used for producing microstructured component parts, for example integrated circuits. The microlithography process is performed using a lithography apparatus, which comprises an illumination system and a projection system. The image of a mask (reticle) illuminated by use of the illumination system is projected by use of the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses that use light having a wavelength in the range from 0.1 nm to 30 nm, in particular 13.5 nm, are currently under development.

The photomask used during microlithography (i.e. the lithography mask) comprises microstructures that are projected onto the substrate with a reduced scale. The structures of the photomask themselves are already very small and have dimensions of a few micrometers to a few nanometers, for example. In order to very accurately produce microstructured components using microlithography, the structures on the utilized photomasks must also be manufactured very precisely, and the photomasks must be free from defects (e.g. defective structures and contaminations). A defect-free microlithographic photomask is also very important because a photomask is usually used for multiple exposures. Therefore, photomasks are examined in regard to defects at great expense, and uncovered defects are repaired.

Typical defects of photomasks include the lack of envisaged structures, for example because an etching process was not carried out successfully, or else there are non-envisaged structures, for example because an etching process proceeded too quickly or developed its effect at a wrong site. These defects can be remedied by targeted etching of excess material or targeted deposition of additional material at the appropriate positions; for example, this is possible in a very targeted manner by use of electron beam-induced processes (FEBIP, “focussed electron beam induced processing”).

DE 10 2017 208 114 A1 describes a method for particle beam-induced etching of a microlithographic photomask. In this case, a particle beam, in particular an electron beam, and an etching gas are provided at a site on the photomask to be etched. The particle beam activates a local chemical reaction between a material of the photomask and the etching gas, as a result of which material is locally removed from the photomask.

### SUMMARY

Against this background, a problem addressed by the present invention is that of improving particle beam-induced etching of a defect of a microlithographic photomask.

According to a first aspect, a method is proposed for particle beam-induced etching of a defect of a microlithographic photomask. The method comprises the steps of:
a) providing an activating particle beam and a first gaseous component, which is activatable by the particle beam, at a surface of the photomask in a region of the defect for the purpose of etching the defect, and subsequently
b) providing an oxygen-containing second gaseous component with a spontaneously oxidizing effect at the surface of the photomask in a passivation region that encompasses the region of the defect, for the purpose of passivating the surface.

Herein, a “component with an oxidizing effect” should be understood to be an oxidizing agent that is capable of oxidizing another substance (e.g. a material of the surface of the photomask). In other words, the other substance (e.g. a material of the surface of the photomask) is oxidized by use of the component with an oxidizing effect.

Consequently, a defect of the photomask may be etched (i.e. ablated and/or removed) in particle beam-induced fashion in a first step a). Thereupon, in a further step b) that follows the etching of the defect, the repair site may be passivated with the aid of the oxygen-containing second gaseous component with a spontaneously oxidizing effect. For example, a surface of the photomask is chemically modified in the passivation region with the aid of the second gaseous component. For example, a passivation layer (e.g. an oxygen-containing layer) may also be generated in the passivation region by way of the chemical modification. In particular, the passivation enables passivation, e.g. chemical modification, of surfaces of structures (e.g. absorber structures) of the photomask that were exposed in step a) by etching. Consequently, these structures are better protected in subsequent processes. Moreover, spontaneous etching of the structure may arise at the surface exposed during the etching, without the second gaseous component being supplied. Spontaneous etching of the structure can be at least partially counteracted by the supply of the second gaseous component.

Within the scope of passivation, reactive species (e.g. F, HF, F compounds) remaining in the surroundings of the repair site for example may be supplanted at the surface of the photomask by adsorption of the second gaseous component. Moreover, within the scope of passivation, species that may serve as an initial material for reactive compounds (e.g. a TaOₐF_{b} species as initial material for reactive fluorine compounds, e.g. HF) may be inactivated by a chemical reaction with the second gaseous component. Furthermore, within the scope of passivation, molecules may be enriched with oxygen at the repair site, and hence the surface may be sealed at the site. For example, tantalum oxyfluorides generated at the repair site may be enriched with oxygen (e.g. TaₐO_{b}F_{c}+O₃→TaₐO_{d}Fₑ, d>b, e<b, should the second gaseous component for example contain ozone (O₃)). This assists the formation of Ta₂O₅, and hence the surface is sealed at the repair site.

For example, the exposed surface of the structure comprises a surface of a side wall of the structure. A material of the structure for example comprises tantalum, one or more tantalum compounds, tantalum nitride and/or tantalum oxide.

In particular, steps a) and b) are two method steps that are separated from one another in time. In other words, repair step a) and passivation step b) are two mutually different processes, which do not run simultaneously. For example, termination of repair step a) is then followed by passivation step b) without a waiting time. Alternatively, a waiting time (e.g. of a few seconds) may be provided between the termination of repair step a) and the start of passivation step b). For example, the waiting time is 60 s or less, 30 s or less, 10 s or less and/or 1 s or less. Passivation step b), i.e. the supply of the second gaseous component, is for example implemented over a period of time of 120 s or less, 100 s or less, 80 s or less and/or 60 s or less.

According to an embodiment, the surface is passivated in step b) without providing the activating particle beam. In particular, there is no particle beam-induced repair (e.g. no particle beam-induced etching) of the photomask during passivation step b). In other words, passivation step b) is a pure passivation step, which is free from particle beam-induced etching of the photomask. For example, the first gaseous component is not (no longer) supplied at a start of the supply of the second gaseous component. However, for operational reasons, there may still be a supply of the first gaseous component to the surface of the photomask within a (short) gas transition time at the start of the supply of the second gaseous component, wherein the first gaseous component is no longer supplied after the expiry of the gas transition time but the second gaseous component continues to be supplied. For example, even at a start of the supply of the second gaseous component, the particle beam is not (no longer) directed at the region of the defect and no longer incident on the photomask in the region of the defect.

For example, the photomask is provided in a process atmosphere. For example, the process atmosphere is an atmosphere with a controlled composition and a controlled pressure (for example lying in the range from 10⁻² to 10⁻⁸ mbar). For example, the process atmosphere is provided within an evacuated housing. Furthermore, the first gaseous component, which is supplied to the surface of the photomask in the region of the defect, is for example provided in the process atmosphere. The second gaseous component, which is supplied to the surface of the photomask in the passivation region, is for example also provided in the process atmosphere. Hereinafter, the evacuated housing in which the process atmosphere is provided is also referred to as a “vacuum chamber.”

In particular, steps a) and b) are performed without the vacuum chamber being opened. In particular, the photomask remains in the vacuum chamber during steps a) and b).

The defect is etched in repair step a), i.e. material is locally removed from the photomask in the region of the defect. As a result, it is possible to remove a superfluous and/or unwanted structure (e.g. an unwanted absorber structure) in the region of the defect by etching.

For example, step a) is preceded by the ascertainment of a repair shape for the defect on the basis of an image of at least a portion of the photomask. In particular, the repair shape of the defect is a geometric shape of the defect in the image. For example, the repair shape is subdivided into a number of pixels. Moreover, the activating particle beam is for example successively provided at each pixel of the repair shape, i.e. focused on the respective pixel, and hence raster-scanned over all pixels of the repair shape.

For example, the region of the defect corresponds to the repair shape of the defect. For example, the particle beam is only provided in the region of the defect (e.g. in the region of the repair shape). Furthermore, the first gaseous component is for example provided at least in the region of the defect. This includes the case that the first gaseous component is for example also provided in an enlarged region of the defect which contains the region of the defect (e.g. the repair shape) and is larger than the region of the defect (e.g. the repair shape).

The passivation region in which the second gaseous component is provided for example completely encompasses (i.e. contains and/or covers) the region of the defect (e.g. the repair shape). For example, the passivation region is larger (i.e. has a larger area) than the region of the defect.

In step a), an activating particle beam in particular is radiated onto the surface of the photomask in the region of the defect. For example, the particle beam may comprise electrons, ions and/or protons. The use of an electron beam is particularly advantageous since firstly the latter can be focused onto a very small incidence surface, and secondly the electrons cause no substantial damage to the irradiated surface. Therefore, the achievable resolution is particularly high when an electron beam is used.

Moreover, the first gaseous component is supplied in step a) to the surface of the photomask, at least in the region of the defect. In particular, the surface of the photomask is a surface on a side of the photomask configured for exposure in an EUV lithography apparatus.

In particular, the first gaseous component comprises an etching gas. For example, the first gaseous component comprises one or more of xenon difluoride (XeF₂), xenon tetrafluoride (XeF₄), sulfur hexafluoride (SF₆), sulfur tetrafluoride (SF₄), nitrogen trifluoride (NF₃), phosphorus trifluoride (PF₃), tungsten hexafluoride (WF₆), tungsten hexachloride (WCl₆), molybdenum hexafluoride (MoF₆), hydrogen fluoride (HF), nitrosyl fluoride (NOF), nitrosyl chloride (NOCl) and/or triphosphorus trinitrogen hexafluoride (P₃N₃F₆).

In addition to the etching gas, the first gaseous component may also comprise other gases, e.g. additive gases. The additive gases may contain oxygen-containing gases, halides (e.g. Cl₂, HCl, XeF₂, CF₄, HF, I₂, HI, Br₂, HBr, NOCl, PCl₃, PCl₅, PF₃ and further halogen-containing gases) and/or gases having reducing action (e.g. H₂, NH₃, CH₄ and other hydrogen-containing gases).

The first gaseous component, e.g. the etching gas, is activated by the particle beam. As a result of this activation, the first gaseous component, e.g. the etching gas, is converted into a reactive form, wherein the reactive form reacts with a material (e.g. an atom or molecule) at the surface of the photomask so as to form a volatile compound. In this way, the surface of the photomask is eroded in the region of the defect.

The microlithographic photomask is for example a photomask for use in an EUV lithography apparatus. In this case, EUV stands for “extreme ultraviolet” and denotes a wavelength of the operating light of between 0.1 nm and 30 nm, in particular 13.5 nm. At these wavelengths it is necessary to use reflective optical elements, and this applies to the photomask as well. In an EUV lithography apparatus, a beam shaping and illumination system is used to guide EUV radiation to the photomask (“reticle”), which takes the form of a reflective photomask. Therefore, the photomask comprises a layer that reflects EUV radiation and e.g. takes the form of a Bragg mirror, and a structured absorbing layer (“absorber structures”) on the reflective surface. Such masks are also referred to as binary lithography masks. The pattern of the structured absorbing layer (i.e. the pattern of the absorber structures) of the photomask is imaged with reduced size on a wafer by use of a projection system of the EUV lithography apparatus.

For example, the microlithographic photomask comprises a substrate, a reflective multilayer coating arranged on the substrate and a structured coating arranged above said reflective multilayer coating. Moreover, a capping layer, for example, may also be arranged between the multilayer coating and the structured coating.

For example, the substrate comprises silicon dioxide (SiO₂), e.g. quartz glass, and/or very low thermal expansion material. For example, the multilayer coating comprises an alternating sequence of molybdenum and silicon layers. For example, the structured coating comprises tantalum, one or more tantalum compounds, tantalum nitride, tantalum boron nitride, tantalum boron oxide and/or tantalum oxide. The substrate, the multilayer coating and/or the structured coating (absorber structures) may also comprise other materials.

On its surface (i.e. on the surface suitable for exposure in the lithography apparatus), the photomask thus for example comprises absorber regions with absorber structures and reflection regions, which are free from absorber structures. Moreover, the defect is for example one or more of the unwanted absorber structures. By way of the proposed method, such a defect of the photomask, i.e. a defect in the form of unwanted, i.e. superfluous, absorber structures of the photomask, can be etched away and hence repaired.

Following etching of the defect, a passivation step is performed in step b). To this end, the second gaseous component is supplied to the surface of the photomask in the passivation region for the purpose of passivating the surface. The second gaseous component is an oxygen-containing gaseous component with a spontaneously oxidizing effect. It can also be said that the second gaseous component causes spontaneous oxidation of a material of the surface of the photomask. That is to say, the second gaseous component triggers a spontaneous chemical reaction with a material of the surface of the photomask. A spontaneous chemical reaction is a chemical reaction that takes place without external compulsion, in particular without an additional activation (e.g. at room temperature and/or at a temperature between 20° and 22° and/or at 21°). In particular, there is no need to activate the second gaseous component by a particle beam in order to achieve the passivation effect of the second gaseous component.

This is an advantage over species without a spontaneous oxidizing effect as passivation gas, which form a deposit or cause a chemical modification of the substrate only under the influence of a particle beam. An example of a species without a spontaneous oxidizing effect as passivation gas is a TEOS gas (here, TEOS represents tetraethyl orthosilicate (Si(OC₂H₅)₄), also referred to as tetraethoxysilane), which forms a deposit, for example silicon dioxide, only under the influence of a particle beam.

For example, the photomask comprises a metal-containing material on the surface, and the second gaseous component spontaneously passivates the metal-containing material (e.g. by spontaneous chemical adsorption). Hence, the second gaseous component is a species with a strongly oxidizing effect, which is able to spontaneously (i.e. without additional activation, in particular without activation by a particle beam) oxidize a metal-containing material (e.g. is able to transfer oxygen atoms to the metal-containing surface). This is an advantage over TEOS, for example, as passivation gas, which is unable to spontaneously oxidize a metal-containing material.

For example, a structured coating (absorber structures) of the photomask comprises a metal-containing material (e.g. tantalum compounds). For example, a capping layer of the photomask comprises a metal-containing material (e.g. ruthenium).

According to an embodiment, at least one edge of a structured coating of the photomask is exposed in step a). Moreover, the at least one exposed edge is passivated in step b).

In particular, the at least one edge of the structured coating that is exposed in step a) is still at least partially exposed at the end of step a).

In particular, the at least one edge of the structured coating is at least one edge that is arranged substantially perpendicular to a main extension plane of the photomask. In this case, “substantially perpendicular” comprises angles between the at least one edge of the photomask and the main extension plane of the photomask of 60° or more, 70° or more, 80° or more, 85° or more and/or approximately exactly 90°.

The at least one edge of the structured coating for example comprises at least one side wall of the structured coating.

According to a further embodiment, the defect is completely etched and/or completely removed in step a).

Hence, the defect, i.e. an unwanted structure (e.g. a geometrically contiguous unwanted structure), may be completely removed in step a). Hence, the defect of the photomask is repaired in full before the surface of the photomask is passivated, in particular at the repair site.

According to a further embodiment, the second gaseous component passivates the surface of the photomask with the aid of spontaneous chemical adsorption.

That is to say, the second gaseous component is chemically adsorbed on a material of the surface of the photomask. In other words, there is a chemical reaction between the second gaseous component and a material of the surface of the photomask. Hence, the material of the surface of the photomask is chemically altered. Chemical adsorption is also referred to as “chemisorption.”

In detail, for example the second gaseous component is chemically adsorbed on a material of the surface of the photomask, and the surface of the photomask is subsequently oxidized by the chemically adsorbed second gaseous component, whereby at least one oxygen atom is irreversibly bound to the surface of the photomask.

Chemical adsorption differs from a physical adsorption (“physisorption”) in that the chemical adsorption comprises a chemical reaction between an adsorbate (the second gaseous component in this case) and an adsorbent (the material of the surface of the photomask in this case). That is to say, adsorbate and/or adsorbent are chemically modified. By contrast, only a physical bond between the adsorbate (second gaseous component) and the adsorbent (material of the surface of the photomask) is created within the scope of physical adsorption. That is to say, adsorbate and adsorbent are not chemically modified in the process, but instead bound to one another by physical forces. For example, this physical bond is based on weakly bonding and hence easily releasable van-der-Waals forces. An example for physical adsorption is found in the accumulation of a TEOS gas on a surface of a photomask. TEOS comprises one or more oxygen-containing compounds, which form non-volatile oligomers on the mask. The non-volatile oligomers are macromolecules formed from individual TEOS molecules, i.e. a concatenation of TEOS molecules among themselves (not with the surface of the photomask). On account of their greater mass (in comparison with individual TEOS molecules), the TEOS oligomers may physisorb on the surface of the photomask for a longer period of time.

According to a further embodiment, the method includes the following step:
c) removing the second gaseous component from the surface of the photomask by pumping.

For example, the second gaseous component is pumped out of the process atmosphere.

For example, steps a), b) and c) are performed without opening the vacuum chamber. In particular, the photomask remains in the vacuum chamber and in the process atmosphere during steps a), b) and c).

According to a further embodiment, a first defect of the photomask is etched in a first region of the photomask in step a). Following step c), the method moreover includes a further step a), in which a second defect of the photomask is etched in a second region of the photomask.

As a result of the surface of the photomask having been passivated with the aid of the second gaseous component following the etching of the first defect, the surface of the photomask is protected for subsequent processing steps. In particular, this can prevent unwanted continuation of an etching procedure at the repair site of the first defect during the etching of the second defect (i.e. during the repetition of step a) for the second defect) when an etching gas is used again.

In particular, the first and second regions of the correspondingly first and second defects are disjoint regions of the photomask. This means that, inter alia, the first and second regions do not overlap one another and are not contiguous with one another.

For example, the first and second regions of the correspondingly first and second defects may each be geometrically contiguous regions on their own.

Step c) may also be performed again following the repetition of step b) for the second defect.

Steps a) and b) and/or a) to c) may be repeated any desired number of times for further defects of the photomask, wherein the further regions of the further defects are in each case disjoint with respect to one another and with respect to the first and second regions of the first and second defects.

For example, the method can be used to etch (e.g. repair) a number n of defects of the photomask, where n is a natural number greater than 1. Then, steps a) to c) may be performed for each of the first (n−1) defects, and steps a) and b) may be performed for the n-th defect. Subsequently, the photomask can be removed from the process atmosphere (e.g. taken out of and/or unloaded from the vacuum chamber).

According to a further embodiment, the second gaseous component contains ozone (O₃), atomic oxygen (O), excited oxygen (O₂*), hydroperoxyl (HOO), hydroxyl (HO), a nitrate radical (NO₃), one or more oxygen radicals and/or one or more neutral oxygen radicals.

Ozone (O₃) is a strong oxidizing agent, which develops its oxidizing effect even at room temperature. On account of its strong oxidizing effect, the gas is already unstable at room temperature. The effect of ozone develops on account of the atomic oxygen that arises during the decomposition of the molecule (decomposition reaction: O₃→O₂+O), is itself highly reactive and has an oxidative effect. Hence, as so-called “active oxygen,” ozone is a carrier of this reactive atomic oxygen. For example, ozone can transfer oxygen atoms to metal surfaces. For example, ozone may also oxidize halides to halogens. Moreover, ozone has a dipole moment of 0.5337 D, promoting surface adsorption.

Oxygen radicals are reactive oxygen species (ROSs) in particular, e.g. oxygen-containing molecules. Herein, oxygen radicals also comprise atomic oxygen.

According to a further embodiment, the second gaseous component contains ozone generated with the aid of an ozonizer. Oxygen is guided through an electric field or exposed to UV light in the ozonizer such that ozone is generated from the oxygen. The generated ozone is supplied to the surface of the photomask through a provision line of the ozonizer and/or through a supply line that is fluid-connected to the ozonizer.

Oxygen may be supplied to the ozonizer as pure oxygen (O₂) or as a constituent of a molecule (e.g. H₂O) or of a mixture (e.g. air).

For example, the ozonizer comprises a chamber through which the oxygen is guided and in which the electric field or the UV light acts on the oxygen.

For example, the provision line of the ozonizer is (e.g. directly) fluid-connected to the chamber. For example, at its end opposite the chamber, the provision line comprises a nozzle through which the ozone is guided to the surface of the photomask.

For example, the ozonizer provides an O₃ flow of 0.1-4 sccm at its output nozzle and/or at the surface of the photomask. This relatively low O₃ flow ensures compatibility with the vacuum system.

According to a further embodiment, the second gaseous component contains one or more neutral oxygen radicals that are generated with the aid of a plasma-based gas generation device. The plasma-based gas generation device comprises a plasma source and a selection device fluid-connected to the plasma source. The one or more neutral oxygen radicals are coupled out of a plasma, which was generated in the plasma source, by use of the selection device and are supplied to the surface of the photomask through a provision line of the plasma-based gas generation device and/or through a supply line that is fluid-connected to the selection device.

Using the plasma source (remote plasma source) and the selection device, it is for example possible to provide atomic oxygen (O), hydroperoxyl (HOO), hydroxyl (HO) and/or nitrate radicals NO₃ as neutral oxygen radicals and hence as second gaseous component.

The plasma-based gas generation device, in particular the plasma source, for example comprises a chamber in which the plasma is generated. The selection device, for example, is arranged at an outlet opening of the chamber. Furthermore, the provision line of the plasma-based gas generation device is (e.g. directly) fluid-connected to the selection device, for example. For example, at its end opposite the selection device, the provision line comprises a nozzle through which the oxygen radical(s) is/are guided to the surface of the photomask.

According to a further embodiment, the first gaseous component contains at least one etching gas component for etching the defect and at least one passivation gas component for passivating the surface of the photomask in a first passivation step. Moreover, the surface of the photomask is passivated in step b) with the aid of the second gaseous component in a second passivation step.

In this embodiment, a further passivation step is already carried out during etching step a), in addition to passivation step b) with the aid of the second gaseous component. In other words, the defect is etched in step a) with the aid of the first gaseous component, and the repair site is passivated at the same time in a first passivation step. Subsequently, a second passivation step is performed in step b) with the aid of the second gaseous component.

In particular, it may be the case that the first passivation step performed during step a) does not lead to a complete passivation of the surface of the photomask. For example, the passivation may be incomplete at edges of the absorber structures. Then, the passivation of the surface may be improved and/or completed using the second later passivation step b).

The passivation gas component contained in the first gaseous component in this embodiment for example comprises one or more of the following substances: oxygen (O₂), ozone (O₃), water (H₂O), hydrogen peroxide (H₂O₂), dinitrogen monoxide (N₂O), nitrogen monoxide (NO), nitrogen dioxide (NO₂), nitric acid (HNO₃) and further oxygen-containing gases.

According to a further embodiment, step b) comprises the following:
a third gaseous component is provided at the surface of the photomask in the passivation region,
the third gaseous component passivates the photomask in the passivation region by physical adsorption, and
the second and third gaseous components are provided simultaneously in a single passivation step or successively in correspondingly two passivation steps that are separated from one another in time.

In this embodiment, a further passivation step with the aid of a third gaseous component is carried out in step b), in addition to the passivation step with the aid of the second gaseous component. While the passivation step with the aid of the second gaseous component is a passivation by chemisorption, the further passivation step with the aid of the third gaseous component comprises passivation by physisorption. As a result, a passivation of the surface of the photomask can be improved even further.

Should the second and third gaseous components be provided simultaneously in a single passivation step, the second and third gaseous component may be provided as a gas mixture, for example.

Should the second and third gaseous components be provided successively in correspondingly two passivation steps that are separated from one another in time, the third gaseous component for physical passivation is for example provided first, and then the second gaseous component for chemical passivation.

Should a further passivation step be additionally performed in step a), the method may thus comprise three mutually different passivation steps, e.g. with three mutually different gases.

The third gaseous component comprises NO₂ and/or TEOS merely by way of example. However, the third gaseous component may also comprise one or more of the other gases.

According to a further embodiment:
the photomask comprises absorber regions with absorber structures and reflection regions, which are free from the absorber structures,
the defect comprises one or more of the absorber structures, which are unwanted and which are etched in step a) with the aid of the first gaseous component,
a fourth gaseous component is provided in step b) at the surface of the photomask,
the reflection regions of the photomask are protected with the aid of the fourth gaseous component from a passivation by the second gaseous component, and
the photomask is passivated in the absorber regions with the aid of the second gaseous component.

With the aid of the fourth gaseous component, reflection regions of the photomask can be protected from a passivation by the second gaseous component. For example, the reflection regions of the photomask comprise the capping layer. For example, the capping layer comprises ruthenium (“Ru capping layer”). The capping layer may be damaged by the second gaseous component which has a strongly oxidizing effect. In order to prevent this, the reflection regions of the photomask may be protected with the aid of the fourth gaseous component from a passivation (i.e. oxidation) by the second gaseous component. The fourth gaseous component is adsorbed, for example physically adsorbed, in the reflection regions of the photomask.

For example, the fourth gaseous component comprises TEOS, tetrafluoromethane (CF₄) and/or nitrogen dioxide (NO₂). The fourth gaseous component may also comprise one or more other substances.

According to a second aspect, an apparatus is proposed for particle beam-induced etching of a defect of a microlithographic photomask. The apparatus comprises:
a first provision device for providing an activating particle beam at a surface of the photomask in a region of the defect,
a second provision device for providing a first gaseous component, which is activatable by the particle beam, at the surface in the region of the defect for the purpose of etching the defect, and
a third provision device for providing an oxygen-containing second gaseous component with a spontaneously oxidizing effect at the surface in a passivation region of the photomask that encompasses the region of the defect, for the purpose of passivating the surface.

For example, the apparatus is a repair apparatus for repairing microlithographic photomasks. For example, the apparatus is a modified scanning electron microscope.

The first provision device for example comprises a particle source (e.g. electron source) for generating the particle beam (e.g. electron beam); a particle beam guiding device (e.g. scanning unit), which is configured to direct the particle beam to a respective pixel of the repair shape of the photomask; a particle beam shaping device (e.g. particle, electron and/or beam optics unit), which is configured to shape, more particularly focus, the particle beam; and at least one detector for capturing secondary electrons and/or backscattered electrons.

In particular, the second and third provision devices are second and third gas provision devices. For example, the second and third provision devices may each be part of an overarching gas provision apparatus. Each of the second and third gas provision devices comprises at least one storage container, which is configured to store the corresponding gaseous component, and/or a gas generation device, which is configured to generate the corresponding gaseous component in situ; a gas quantity flow rate setting unit, which is configured to provide the corresponding gaseous component with a predetermined gas quantity flow rate at the surface of the photomask in the corresponding region (e.g. also one or more valves); a supply unit (e.g. with a supply line), which is configured to supply the corresponding gaseous component to the surface of the photomask.

In step a), the activating particle beam is successively provided at each pixel of the repair shape, for example using the particle beam guiding device. The activating particle beam remains at each pixel for a predetermined dwell time in order to initiate the chemical reaction between the first gaseous component and the mask material at the location of the respective pixel. For example, the dwell time is 100 ns. However, the dwell time may also adopt other values.

According to an embodiment of the second aspect, the apparatus comprises:
an ozonizer for generating ozone from oxygen, wherein the ozonizer comprises a capacitor for generating an electric field or a UV light source for generating a UV light, and
a provision line for providing the generated ozone as the second gaseous component at the surface of the photomask.

According to a further embodiment of the second aspect, the apparatus comprises a plasma-based gas generation device for generating the second gaseous component. The plasma-based gas generation device comprises a plasma source for generating a plasma, a selection device for coupling one or more neutral oxygen radicals out of the plasma, and a provision line for providing the one or more decoupled neutral oxygen radicals at the surface of the photomask.

For example, the plasma is generated out of oxygen. In particular, the plasma is generated in a plasma chamber of the plasma source and only exists in the plasma chamber. Then, one or more neutral oxygen radicals are extracted from the plasma with the aid of the selection device.

The ozonizer or the plasma-based gas generation device allows the second gaseous component to be generated in situ at the location of the apparatus for particle beam-induced etching.

“A” or “an” in the present case should not necessarily be understood as a restriction to exactly one element. Rather, there may also be multiple elements, for example two, three or more. Any other numeral used here should also not be understood as a restriction to exactly the stated number of elements. Rather, unless indicated otherwise, numerical deviations upwards and downwards are possible.

The embodiments and features described for the method apply correspondingly to the proposed apparatus, and vice versa.

Further possible implementations of the invention also comprise non-explicitly mentioned combinations of features or embodiments described hereinabove or hereinafter with regard to the exemplary embodiments. A person skilled in the art will also add individual aspects as improvements or supplementations to the respective basic form of the invention.

Further advantageous embodiments and aspects of the invention are the subject matter of the dependent claims and of the exemplary embodiments of the invention described below. The invention is explained in greater detail hereinafter on the basis of preferred embodiments with reference to the accompanying figures.

### BRIEF DESCRIPTION OF DRAWINGS

FIG. 1 schematically shows, according to an embodiment, a section through a microlithographic photomask which is undergoing a particle beam-induced processing process, wherein the upper image illustrates a particle beam-induced repair process for a defect, and the lower image illustrates a passivation of the repair site;

FIG. 2 shows a flowchart of a method for particle beam-induced etching of a defect of a microlithographic photomask, according to an embodiment;

FIG. 3 shows an apparatus for particle beam-induced etching of a defect of a microlithographic photomask, according to an embodiment;

FIG. 4 shows a gas generation device of the apparatus from FIG. 3, according to an embodiment;

FIG. 5 shows a gas generation device of the apparatus from FIG. 3, according to a further embodiment;

FIG. 6 shows a plan view of a microlithographic photomask, according to an embodiment;

FIG. 7 illustrates variants of method steps of the method from FIG. 2; and

FIG. 8 shows an apparatus for particle beam-induced etching of a defect of a microlithographic photomask, according to a further embodiment.

### DETAILED DESCRIPTION

In the figures, identical or functionally identical elements have been provided with the same reference signs, unless indicated otherwise. It should also be noted that the representations in the figures are not necessarily to scale.

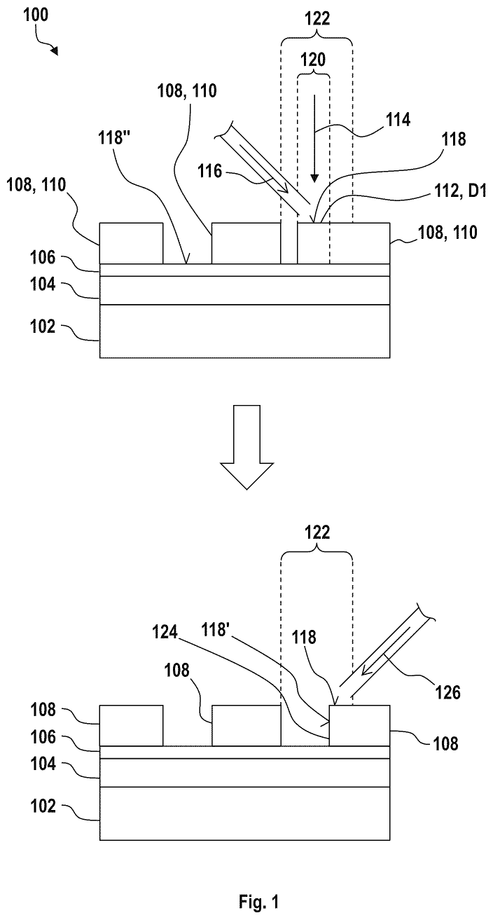

FIG. 1 shows schematically a section through a photomask 100, which is undergoing a particle beam-induced processing process. In particular, this process is a locally induced etching process, in which material is removed from the photomask 100.

In the illustrated example of the photomask 100, the mask is a mask suitable for EUV lithography and operated on a reflective basis. That is to say, in operation, the operating light is radiated onto the photomask 100 and reflected back into the same half-space. EUV stands for “extreme ultraviolet” (EUV) and refers to a wavelength of the operating light between 0.1 nm and 30 nm, in particular 13.5 nm.

In the example of FIG. 1, the photomask 100 has a layer-like structure. The base of the photomask 100 is formed by a substrate 102, which may comprise quartz glass for example. A multilayer mirror 104 is arranged on the substrate 102. In particular, the multilayer mirror 104 is arranged on the side of the substrate 102 that is subsequently irradiated by the operating light during operation. For example, the multilayer mirror 104, as a Bragg mirror, is designed specifically for the respective wavelength of the operating light. For example, the multilayer mirror 104 comprises a plurality of double layers made of molybdenum and silicon. A capping layer 106 is arranged on the multilayer mirror 104. For example, the capping layer 106 comprises ruthenium or another noble metal. For example, the capping layer 106 is an etch stop layer, which is configured to halt etching processes utilized in the structuring of the structured layer 108, so that the multilayer mirror 104 or the substrate 102 are not attacked in the process.

A structured layer 108 is arranged on the capping layer 106, and the pattern of said structured layer should be projected onto a wafer in an image plane of a projection system of the lithography apparatus. Reference sign 110 denotes a plurality of structures of the structured layer 108. For example, the structured layer 108 comprises tantalum boron nitride TaBN, tantalum nitride TaN, tantalum boron oxide TaBO and/or tantalum oxide TaO. For example, a layer of TaBN is first applied over the full area and then selectively etched in order to produce the structured layer 108. The incident operating light is greatly attenuated in regions in which the TaBN layer remains.

Defects D1 may arise when the photomask 100 is produced. FIG. 1 shows an opaque defect D1, in which an absorber structure 112 is arranged at a site on the photomask 100 where there should be no absorber structure. In other words, the absorber structures 110 in FIG. 1 are desired absorber structures, while the absorber structure 112 is an unwanted and superfluous absorber structure.

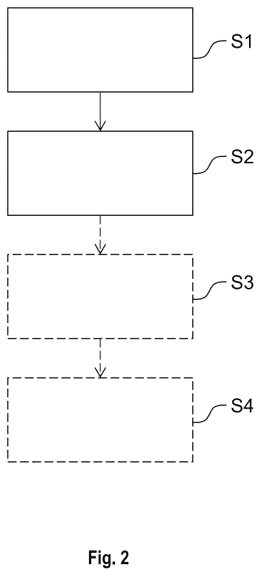

Hereinafter, a method for particle beam-induced etching of a defect D1 of a microlithographic photomask 100 is described with reference to FIGS. 1 to 8, in particular FIG. 2.

The defect D1 is etched in a particle beam-induced process in a first step S1 of the method. The first step S1 is illustrated in the upper image of FIG. 1. An activating particle beam 114 (e.g. an electron beam) and a first gaseous component 116, which is activatable by the particle beam 114, in particular are provided in step S1 at a surface 118 of the photomask 100 in a region 120 of the defect D1. In particular, the first gaseous component 116 comprises an etching gas, for example XeF₂.

For example, one or more edges 124 (FIG. 1, bottom) of the structures 108 are exposed when etching the defect D1 in step S1.

For example, the defect D1 may be completely etched, i.e. completely removed, in step S1. In this case, the unwanted structure 112 is completely removed at the end of step S1.

In a second step S2 of the method, the surface 118 of the photomask 100 is passivated in a passivation region 122. In particular, the second step S2 is carried out after the first step S1, in which the defect D1 is etched. The second step S2 is illustrated in the lower image of FIG. 1, in which the photomask 100 is visible without the defect D1, 112.

In particular, a second gaseous component 126 is provided at the surface 118 of the photomask 100 in the passivation region 122 of the photomask 100 in step S2. The passivation region 122 encompasses the region of the defect 120 (FIG. 1, top), completely in particular, and is for example larger than the latter. The second gaseous component 126 is an oxygen-containing gaseous component with a spontaneously oxidizing effect. The second gaseous component 126 comprises a highly reactive species, e.g. ozone or a different oxygen radical, and passivates the surface 118 of the photomask 100 without additional activation, i.e. without activation by a particle beam (e.g. without the particle beam 114 shown in the top image of FIG. 1). In particular, the second gaseous component 126 passivates the surface 118 of the photomask 100 by spontaneous chemical adsorption, wherein the surface 118 is chemically altered. In particular, the nature of the second gaseous component 126 is such that it is able to spontaneously oxidize (i.e. without activation by a particle beam) a metal-containing material on the surface 118 of the photomask 100, for example a metal-containing material (e.g. a tantalum compound and/or tantalum) of the structured coating 108.

Passivation in step S2 makes it possible in particular to passivate exposed surfaces 118′ of edges 124 of the structures 108 that were exposed during the etching in step S1.

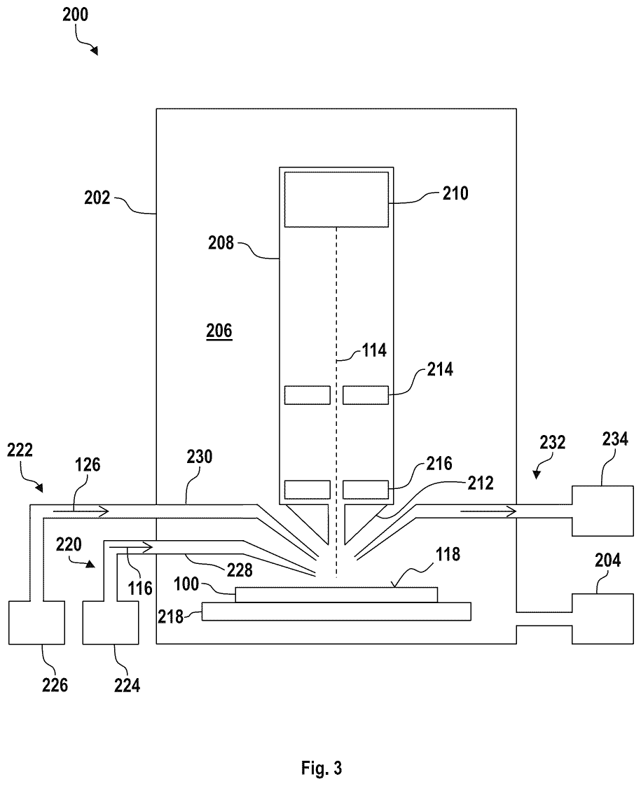

FIG. 3 shows a schematic drawing of an apparatus 200 for particle beam-induced etching of a photomask 100, for example the EUV photomask 100 from FIG. 1.

The apparatus 200 comprises a housing 202 which is evacuated by a vacuum pump 204 to a pressure in the range of 10⁻²-10⁻⁸ mbar in order to create a process atmosphere 206 in the housing 202. The apparatus 200 moreover comprises a provision device 208, arranged in the vacuum housing 202, for the provision of a focussed particle beam 114. The provision device 208 comprises a particle source 210 and one or more beam guiding and/or beam shaping units 212, 214, which steer the particle beam 114 as desired to the surface 118 of the photomask 100. For example, the provision device 208 is an electron column, which is configured to provide a focused electron beam 114. Moreover, the apparatus 200 comprises one or more detectors 216, e.g. for the detection of secondary electrons.

The apparatus 200 moreover comprises a sample stage 218 for holding and positioning the photomask 100 to be processed. The sample stage 218 is actuatable in two or preferably in three spatial directions. Moreover, the sample stage 218 may be mounted in tiltable and rotatable fashion in order to position the photomask 100. In particular, the sample stage 218 is mounted with vibration damping and is mechanically decoupled (not shown) from the rest of the structure.

Moreover, the apparatus 200 comprises a first and a second gas provision device 220, 222, accordingly for the provision of the first and second gaseous components 116, 126. The first and a second gas provision device 220, 222 are for example partly arranged outside of the housing 202. Each of the first and second gas provision devices 220, 222 comprises at least one storage container 224, 226 or a gas generation device 224, 226. Each of the first and second gas provision devices 220, 222 moreover comprises means for setting a gas quantity flow rate and means for starting and ending a gas flow. Moreover, each of the first and second gas provision devices 220, 222 comprises a supply line 228, 230, which leads into the housing 202 and opens into a respective nozzle at its end. Additionally, further gas provision devices similar to the gas provision devices 220, 222 may be provided in order to supply further gaseous components, for example buffer gases, gases with an oxidizing effect or reducing effect, to the process atmosphere 206.

Moreover, a suctioning unit 232 is depicted in FIG. 3. The suctioning unit 232 is configured to suction away excess gas and, in particular, volatile reaction products from the process atmosphere 206, in particular from the surface 118 of the photomask 100. To this end, the suctioning unit 232 for example comprises a further pump 234. This allows better control of the composition of the process atmosphere 206.

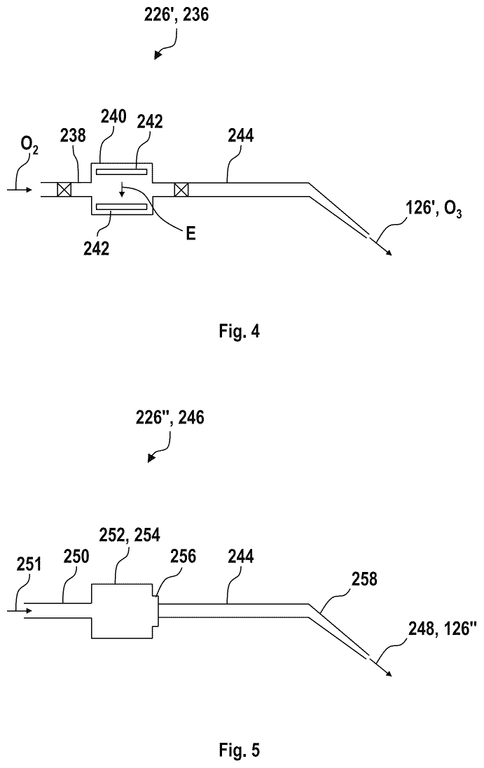

FIGS. 4 and 5 each illustrate embodiments of the second gas generation device 226′, 226″ for generating the second gaseous component 126, 126′, 126″. In particular, the second gaseous component 126, 126′, 126″ is a highly reactive species, which is preferably generated adjacent to its use location.

FIG. 4 shows an ozonizer 236 for generating ozone O₃ as second gaseous component 126′. The ozonizer 236 comprises a supply line 238 for supplying oxygen O₂. Oxygen O₂ may be supplied to the ozonizer 236 as pure oxygen O₂ or as a constituent of a molecule (e.g. H₂O) or of a mixture (e.g. air). Furthermore, the ozonizer 236 comprises a chamber 240, in which the oxygen O₂ is exposed to a strong electric field E (capacitor 242) for example, whereby ozone O₃ is formed from the oxygen O₂. Moreover, the ozonizer 236 comprises a provision line 244 for providing the ozone O₃ that has formed. For example, the provision line 244 is the supply line 230, shown in FIG. 3, for supplying the second gaseous component 126, 126′ to the photomask 100. Alternatively, the provision line 244 is fluid-connected to the supply line 230 in FIG. 3.

FIG. 5 shows a plasma-based gas generation device 246 for generating one or more neutral oxygen radicals 248 as second gaseous component 126″. The plasma-based gas generation device 246 comprises a supply channel 250 for supplying a work gas 251 (e.g. oxygen) into a chamber 252, the chamber 252 with a plasma source 254 for generating a plasma, a selection device 256 for extracting the one or more neutral oxygen radicals 248 from the plasma and a provision line 258 for providing the neutral oxygen radicals 248 that have been generated. For example, the provision line 258 is the supply line 230, shown in FIG. 3, for supplying the second gaseous component 126, 126″ to the photomask 100. Alternatively, the provision line 258 is fluid-connected to the supply line 230 in FIG. 3. For example, atomic oxygen (O), hydroperoxyl (HOO), hydroxyl (HO) and/or NO₃ may be provided using the plasma-based gas generation device 246 as neutral oxygen radicals 248 and hence as second gaseous component 126″.

In an optional third step S3 of the method, the second gaseous component 126 is removed from the surface 118, 118′ of the photomask 100 by pumping. For example, the suctioning unit 232 with the further pump 234, shown in FIG. 3, is used to this end.

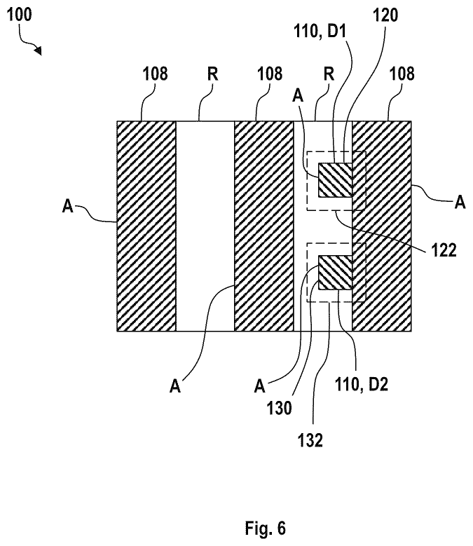

In an optional fourth step S4 of the method, step S1 is carried out again after step S3—albeit for a different second defect D2 of the photomask (FIG. 6).

In particular, a first defect D1 of the photomask 100 in a first region 120 of the photomask 100 is etched during the first implementation of step S1 (FIGS. 1, 6). Furthermore, the surface 118 of the photomask 100 (e.g. the surface 118′ of exposed edges 124 of the structures 108, FIG. 1) is passivated in a first implementation of step S2. Step S3 is thereupon carried out and the second gaseous component 126 is removed from the surface 118, 118′ of the photomask 100 by pumping. Subsequently the second defect D2 (FIG. 6) of the photomask 100 is etched in a second region 130 of the photomask 100 during a second implementation of step S1.

Optionally, step S2 for passivating the surface 118 of the photomask 100 can subsequently be carried out anew for a second passivation region 132 (FIG. 6), which contains the second region 130 of the second defect D2.

Similarly, a plurality of further defects (not shown) of the photomask 100, which are similar to the defects D1, D2, may be etched, and the corresponding repair sites may be passivated by repeated implementation of steps S1 and S2 or S1 to S3.

Steps S1 to S3 including possible repetitions of steps S1 and S2 or S1 and S3 for further defects are for example carried out without removing the photomask 100 from the process atmosphere 206. In other words, the photomask 100 remains in the vacuum chamber 202 during these method steps, and the vacuum chamber 202 remains closed.

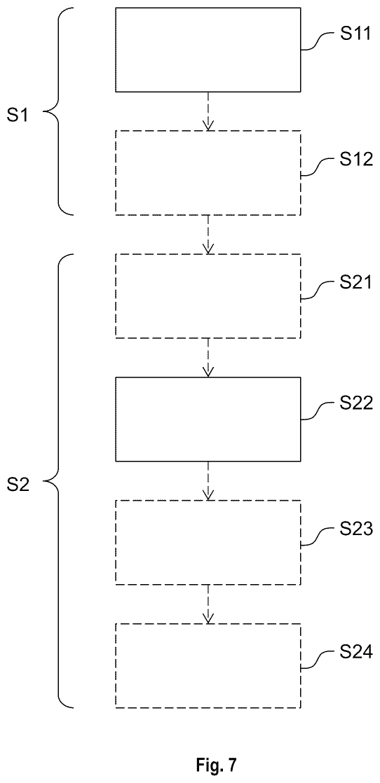

FIG. 7 illustrates variants of method steps S1 and S2.

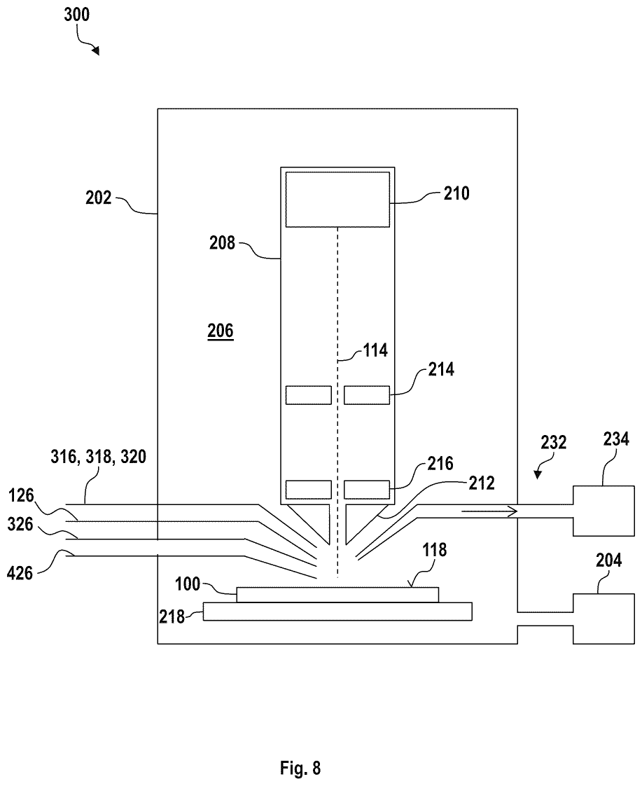

In a first variant of the method, method step S1 may comprise a passivation step S12 for passivating the surface 118 of the photomask 100 in addition to the above-described etching step (referred to as step S11 hereinafter). This means that the method comprises two mutually independent passivation steps. In particular, the method comprises a pre-passivation step S12 with a pre-passivation gas 318 during the etching S11 (FIG. 8) and a main passivation step S2 (or S22) with a main passivation gas 126 following the etching S11.

In the first variant of the method, the first gaseous component 316 (see apparatus 300 in FIG. 8) comprises at least one passivation gas 320 for passivating the surface 118 of the photomask 100, in addition to an etching gas 318 for etching the defect D1. For example, the passivation gas 320 comprises H₂O. For example, the passivation gas 320 is a passivation gas which only has a passivating effect upon activation by a particle beam 114.

In step S1 in this first variant of the method, the defect D1 is etched (with the etching gas 318) with the aid of the first gaseous component 316 (in particular in partial step S11), and the repair site is simultaneously passivated (with the passivation gas 320) in a first pre-passivation step S12. Subsequently, a second passivation step is performed in step S2 with the aid of the second gaseous component 126.

Especially if the pre-passivation step S12 does not lead to a complete passivation of the surface 118, 118′ of the photomask 100, and e.g. the passivation is incomplete at edges 124 (FIG. 1) of the absorber structures 108, the passivation of the surface 118 can advantageously be completed using the second subsequent main passivation step S2.

In a second variant of the method, method step S2 may include a step S21 of generating the second gaseous component 126, 126′, 126″. In particular, the second gaseous component 126, 126′, 126″ is generated in situ at the location of the apparatus 200, 300 in this case. For example, the second gaseous component 126, 126′, 126″ is generated using an ozonizer 236 (FIG. 4) or using a plasma-based gas generation device 246 (FIG. 5).

In a third variant of the method, method step S2 may include a further passivation step S23. In this case, method step S2 comprises two passivation processes S22 and S23: In addition to the above-described passivation process with the aid of the second gaseous component 126, 126′, 126″ (denoted S22 hereinafter), a further passivation process S23 is carried out with the aid of a third gaseous component 326.

In particular, the third gaseous component 326 is provided at the surface 118 of the photomask 100 in the passivation region 122, which encompasses the defect region 120. The third gaseous component 326 passivates the photomask 100 in the passivation region 122 by physical adsorption. For example, the third gaseous component 326 comprises NO₂ and/or TEOS. The passivation of the surface 118 of the photomask 100 at the repair site can be improved even more by the passivation with the aid of the second gaseous component 126 based on chemisorption of the surface 118 and additionally the passivation with the aid of the third gaseous component 326 based on physisorption.

In the third variant of the method, the second and third gaseous components 126, 326 may be provided simultaneously in a single passivation step S22+S23, for example as a gas mixture (e.g. two thirds of the second gaseous component 126 and one third of the third gaseous component 326, or else a different mixing ratio). Alternatively, the second and third gaseous components 126, 326 may also be provided successively in correspondingly two passivation steps S22, S23 that are separated from one another in time. The third gaseous component 326 for physical passivation is for example provided first in this case, and then the second gaseous component 126 for chemical passivation. However, the reverse sequence is also possible.

Should the further passivation step S12 be additionally performed, the method may consequently comprise three mutually different passivation processes/steps S12, S22, S23 with three mutually different passivation gases 126, 320, 326.

In a fourth variant of the method, method step S2 may include a step S24, in which a fourth gaseous component 426 is supplied to the surface 118 of the photomask 100 in order to protect regions R (FIG. 6) of the photomask 100 which should not be passivated from passivation by the second gaseous component 126.

In particular, the photomask 100 comprises absorber regions A with absorber structures 108 and reflection regions R (FIG. 6), which are free from the absorber structures 108. For example, the reflection regions R comprise a surface 118″ of the capping layer 106 (FIG. 1). Furthermore, the defect D1 comprises one or more of the absorber structures 108, 110, in particular unwanted absorber structures 112 (FIG. 1). These unwanted absorber structures 112 are etched in step S1 with the aid of the first gaseous components 126. Then, both the first gaseous component 126 (in partial step S22) and the fourth gaseous component 426 (in partial step S24) are provided at the surface 118, 118′, 118″ of the photomask 100 in step S2. As a result, the reflection regions R of the photomask 100 are protected from passivation by the second gaseous component 126 with the aid of the fourth gaseous component 426, for example as a result of physical adsorption of the fourth gaseous component 426 in the reflection regions R. Moreover, the photomask is passivated in the absorber regions A with the aid of the second gaseous component 126.

Individual ones, several or all of the first to fourth variants of the method may be combined with one another as well.

Although the present invention has been described on the basis of exemplary embodiments, it is modifiable in diverse ways.

### LIST OF REFERENCE SIGNS

100 Photomask
102 Substrate
104 Multilayer mirror
106 Capping layer
108 Layer
110, 112 Absorber structure
114 Particle beam
116 Component
118, 118′, 118″ Surface
120 Region
122 Region
124 Edge
126, 126′, 126″ Component
130 Region
132 Region
200 Apparatus
202 Housing
204 Vacuum pump
206 Process atmosphere
208 Provision device
210 Particle source
212, 214 Unit
216 Detector
218 Sample stage
220, 222 Gas provision device
224, 226 Storage container/gas generation device
226′, 226″ Gas generation device
228 Supply line
230 Supply line
232 Suctioning unit
234 Pump
236 Ozonizer
238 Supply line
240 Chamber
242 Capacitor
244 Provision line
246 Gas generation device
248 Oxygen radical
250 Supply channel
251 Work gas
252 Chamber
254 Plasma source
256 Selection device
258 Provision line
300 Apparatus
316 Component
318 Gas
320 Gas
326, 426 Component
A Region
D₁, D₂ Defect
E Electric field
O₂ Oxygen
R Region
S1-S4 Method steps
S11, S12 Method steps
S21-S24 Method steps

What is claimed is:

1. A method for particle beam-induced etching of a defect of a microlithographic photomask, including the steps of:
a) providing an activating particle beam and a first gaseous component, which is activatable by the particle beam, at a surface of the photomask in a region of the defect for the purpose of etching the defect, and subsequently
b) providing an oxygen-containing second gaseous component with a spontaneously oxidizing effect at the surface of the photomask in a passivation region that encompasses the region of the defect, for the purpose of passivating the surface.

2. The method according to claim 1, wherein the surface is passivated in step b) without providing the activating particle beam.

3. The method according to claim 1, wherein
in step a) at least one edge of a structured coating of the photomask is exposed, and
the at least one exposed edge is passivated in step b).

4. The method according to claim 1, wherein the defect is completely etched and/or completely removed in step a).

5. The method according to claim 1, wherein the second gaseous component passivates the surface of the photomask with the aid of spontaneous chemical adsorption.

6. The method according to claim 1, including a step:
c) removing the second gaseous component from the surface of the photomask by pumping.

7. The method according to claim 6, wherein
in step a) a first defect of the photomask is etched in a first region of the photomask, and
following step c) the method includes a further step a), in which a second defect of the photomask is etched in a second region of the photomask.

8. The method according to claim 1, wherein the second gaseous component contains ozone (O₃), atomic oxygen (O), excited oxygen (O₂ *), hydroperoxyl (HOO), hydroxyl (HO), a nitrate radical NO₃, one or more oxygen radicals and/or one or more neutral oxygen radicals.

9. The method according to claim 1, wherein
the second gaseous component contains ozone (O₃) generated with the aid of an ozonizer,
oxygen (O₂) is guided through an electric field or exposed to UV light in the ozonizer such that ozone (O₃) is generated from the oxygen (O₂), and
the generated ozone (O₃) is supplied to the surface of the photomask through a provision line of the ozonizer and/or through a supply line that is fluid-connected to the ozonizer.

10. The method according to claim 1, wherein
the second gaseous component contains one or more neutral oxygen radicals that are generated with the aid of a plasma-based gas generation device,
the plasma-based gas generation device comprises a plasma source and a selection device fluid-connected to the plasma source, and
the one or more neutral oxygen radicals are coupled out of a plasma, which was generated in the plasma source, by use of the selection device and are supplied to the surface of the photomask through a provision line of the plasma-based gas generation device and/or through a supply line that is fluid-connected to the selection device.

11. The method according to claim 1, wherein
the first gaseous component contains at least one etching gas component for etching the defect and at least one passivation gas component for passivating the surface of the photomask in a first passivation step, and
the surface of the photomask is passivated in step b) with the aid of the second gaseous component in a second passivation step.

12. The method according to claim 1, wherein in step b):
a third gaseous component is provided at the surface of the photomask in the passivation region,
the third gaseous component passivates the photomask in the passivation region by physical adsorption, and
the second and third gaseous components are provided simultaneously in a single passivation step or successively in correspondingly two passivation steps that are separated from one another in time.

13. The method according to claim 1, wherein
the photomask comprises absorber regions with absorber structures and reflection regions, which are free from the absorber structures,
the defect comprises one or more of the absorber structures, which are unwanted and which are etched in step a) with the aid of the first gaseous component,
a fourth gaseous component is provided in step b) at the surface of the photomask,
the reflection regions of the photomask are protected with the aid of the fourth gaseous component from a passivation by the second gaseous component, and
the photomask is passivated in the absorber regions with the aid of the second gaseous component.

14. An apparatus for particle beam-induced etching of a defect of a microlithographic photomask, comprising:
a first provision device for providing an activating particle beam at a surface of the photomask in a region of the defect,
a second provision device for providing a first gaseous component, which is activatable by the particle beam, at the surface in the region of the defect for the purpose of etching the defect, and
a third provision device for providing an oxygen-containing second gaseous component with a spontaneously oxidizing effect at the surface in a passivation region of the photomask that encompasses the region of the defect, for the purpose of passivating the surface.

15. The apparatus according to claim 14, comprising
an ozonizer for generating ozone (O₃) from oxygen (O₂), wherein the ozonizer comprises a capacitor for generating an electric field or a UV light source for generating a UV light, and
a provision line for providing the generated ozone (O₃) as the second gaseous component at the surface of the photomask.

16. The apparatus according to claim 14, comprising a plasma-based gas generation device for generating the second gaseous component, wherein the plasma-based gas generation device comprises a plasma source for generating a plasma, a selection device for coupling one or more neutral oxygen radicals out of the plasma, and a provision line for providing the one or more decoupled neutral oxygen radicals at the surface of the photomask.

17. The apparatus of claim 15, comprising a plasma-based gas generation device for generating the second gaseous component, wherein the plasma-based gas generation device comprises a plasma source for generating a plasma, a selection device for coupling one or more neutral oxygen radicals out of the plasma, and a provision line for providing the one or more decoupled neutral oxygen radicals at the surface of the photomask.

18. The method of claim 2, wherein
in step a) at least one edge of a structured coating of the photomask is exposed, and
the at least one exposed edge is passivated in step b).

19. The method of claim 2, wherein the defect is completely etched and/or completely removed in step a).

20. The method of claim 2, wherein the second gaseous component passivates the surface of the photomask with the aid of spontaneous chemical adsorption.
